(19) United States
(12) Patent Application Publication
(10) Pub. No.: US 2026/0255708 A1
(43) Pub. Date: Aug. 27, 2026

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Weilung Lu, Tempe, AZ (US); Lawrence Natan, Chandler, AZ (US); Adrian Arcedera, Chandler, AZ (US); Won Bae Bang, Incheon (KR); Ki Dong Sim, Gyeonggi-do (KR)

(73) Assignee: Amkor Technology Singapore Holding Pte. Ltd., Singapore (SG)

(21) Appl. No.: 19/064,521

(22) Filed: Feb. 26, 2025

(51) Int. Cl. H10F 39/00

(52) U.S. Cl. CPC H10F 39/804; H10F 39/026; H10F 39/811

(57) ABSTRACT

In one example, an electronic device comprises a substrate comprising a first side, a second side opposite to the first side, a dielectric structure, and a conductive structure, a first electronic component over the first side of the substrate, wherein the first electronic component comprises an image component at a first side of the first electronic component facing away from the substrate, and an encapsulant over the first side of the substrate and over the first side of the first electronic component. The encapsulant defines a cavity over the first side of the first electronic component, and the image component is exposed in the cavity. The electronic device further comprises an interconnect in the encapsulant and coupled with the first electronic component and the conductive structure, and a lid over the cavity and covering the image component. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2H show cross-sectional views of an example method for manufacturing an example electronic device.

FIG. 3 shows a cross-sectional view of an example electronic device.

FIG. 4 shows a cross-sectional view of an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or.” As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features. The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements. As used herein, the term “coupled” can refer to a mechanical or electrical coupling.

### DESCRIPTION

In one example, an electronic device comprises a substrate comprising a first side, a second side opposite to the first side, a dielectric structure, and a conductive structure, a first electronic component over the first side of the substrate, wherein the first electronic component comprises an image component at a first side of the first electronic component facing away from the substrate, and an encapsulant over the first side of the substrate and over the first side of the first electronic component. The encapsulant defines a cavity over the first side of the first electronic component, and the image component is exposed in the cavity. The electronic device further comprises an interconnect in the encapsulant and coupled with the first electronic component and the conductive structure, and a lid over the cavity and covering the image component.

In another example, an electronic device comprises a substrate comprising a top side, a bottom side, a dielectric structure, and a conductive structure, a first electronic component over the top side of the substrate, wherein the first electronic component comprises a first image component at a top of the first electronic component facing away from the substrate, a second electronic component over the top side of the substrate, wherein the second electronic component comprises a second image component at a top side of the first electronic component facing away from the substrate, and an encapsulant over the top side of the substrate and over the top side of the first electronic component and the top side of the second electronic component. The encapsulant defines a first cavity over the top side of the first electronic component and a second cavity over the top side of the second electronic component, the first image component is in the first cavity and uncovered by the encapsulant, and the second image component is in the second cavity and uncovered by the encapsulant. The electronic device further comprises a first interconnect in the encapsulant and coupled with the first electronic component and the conductive structure, a second interconnect in the encapsulant and coupled with the second electronic component and the conductive structure, and a first lid over the encapsulant and covering at least one of the first cavity or the second cavity.

In yet another example, a method to manufacture and electronic device comprises providing a substrate comprising a first side, a second side opposite to the first side, a dielectric structure, and a conductive structure, providing an electronic component over the first side of the substrate, wherein the electronic component comprises an image component at a first side of the electronic component facing away from the substrate, providing an interconnect coupled to the first side of the electronic component and the first side of the substrate, and providing an encapsulant over the first side of the substrate and over the first side of the electronic component. The encapsulant defines a cavity over the first side of the electronic component, the image component is exposed in the cavity, and the interconnect is in the encapsulant. The method further comprises providing a lid over the cavity and covering the image component.

Other examples are included in the present disclosure. Such examples may be found in the figures, in the claims, or in the description of the present disclosure.

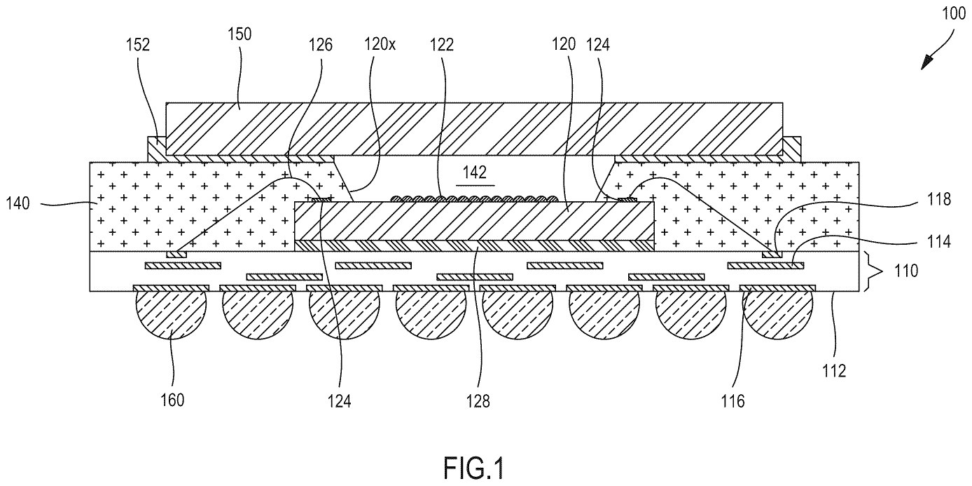

FIG. 1 shows a cross-sectional view of an example electronic device 100. In the example shown in FIG. 1, electronic device 100 can comprise substrate 110 which can comprise dielectric structure 112 and conductive structure 114. Electronic device 100 can comprise electronic component 120 over a top side or a first side substrate 110. Electronic device 100 can have image component 122 at or on a top side or first side of electronic component 120. Image component 122 can face away from substrate 110. In some examples, electronic component 120 can be coupled with the top side or first side of substrate 110 using adhesive 128. Adhesive 128 can be between the bottom side or second side of electronic device 120 and the top side or first side of substrate 110. External interconnect 160 can coupled with the bottom side or second side of substrate 110, and can be coupled with outward terminal 116 of conductive structure 114.

Electronic device 100 can comprise encapsulant 140 over or coupled with the top side or first side of substrate 110. In some examples, a lateral side of encapsulant 140 can be flush with or coplanar with a lateral side of substrate 110. In some examples, a lateral side of encapsulant 140 can be exposed from a lateral side of electronic device 100. Encapsulant 140 can cover a lateral side of electronic component 120 or a top side or a first side electronic component 120. The top side or first side of electronic component 120 can include contact 124, and conductive structure 114 of substrate 110 can include inward terminal 118 at the top side of substrate 110 or exposed at the top side of substrate 110. Interconnect 126 such as a wire can be coupled with contact 124 and inward terminal 118. In some examples, interconnect 126 can be in encapsulant 140, and encapsulant 140 can cover contact 124 or inward terminal 118. Cavity 142 can be defined by the inner sidewall 120x of encapsulant 140 over the top side of electronic component 120. Electronic device 100 can comprise lid 150 disposed over the top side of electronic component 120 and over cavity 142. In some examples, lid 150 can be coupled with the top side or first side of encapsulant 140 using adhesive 152.

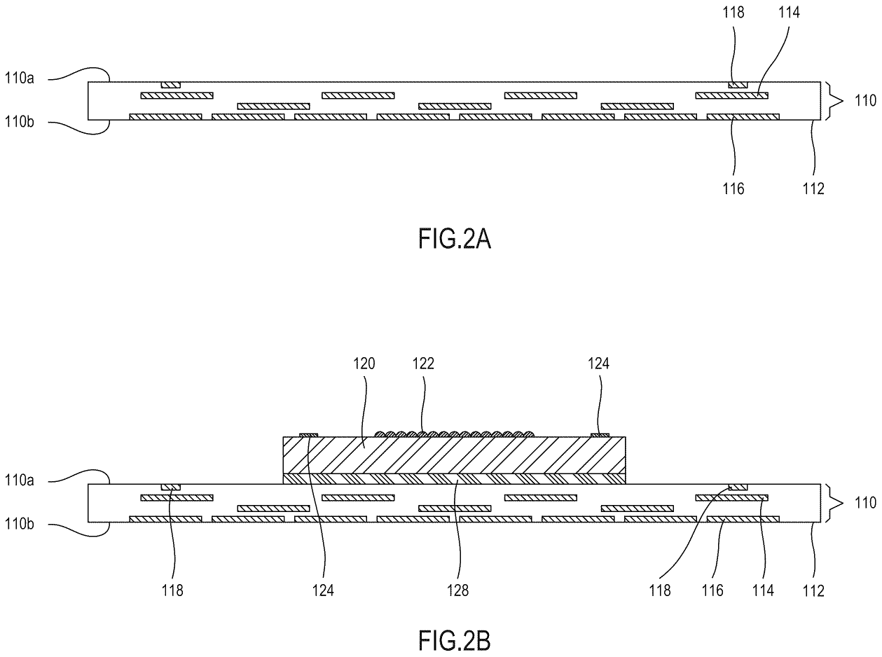

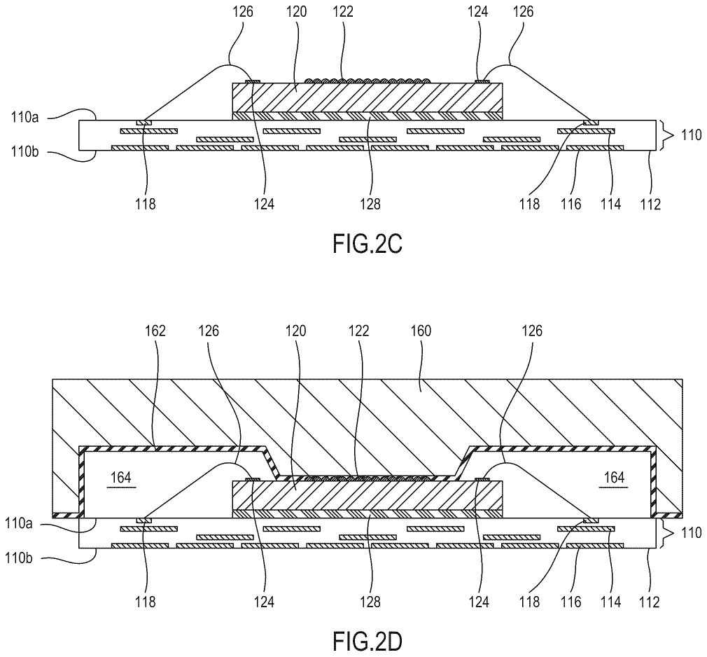

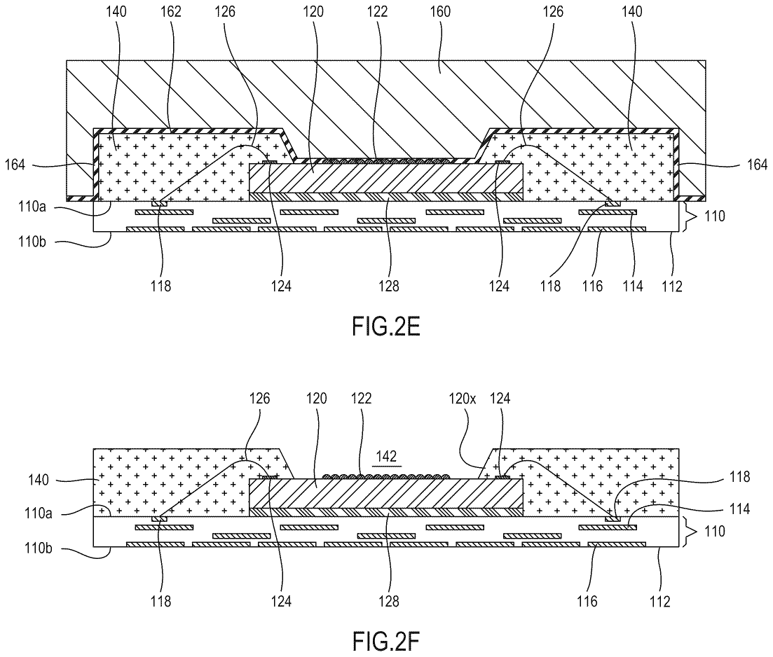

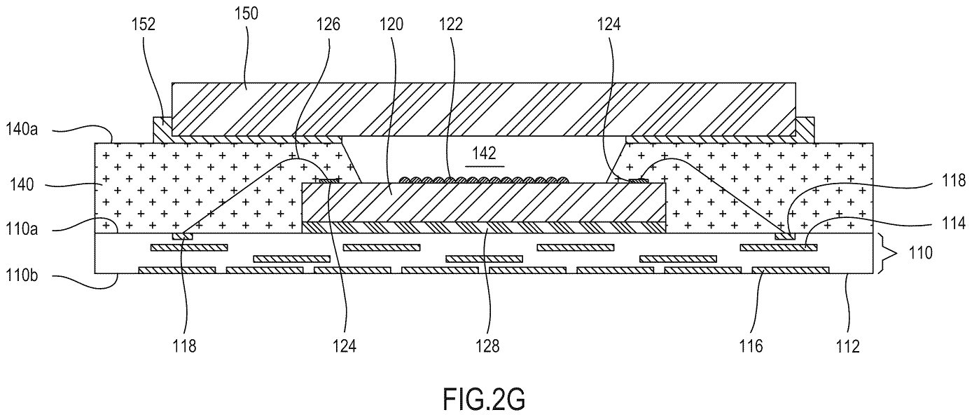

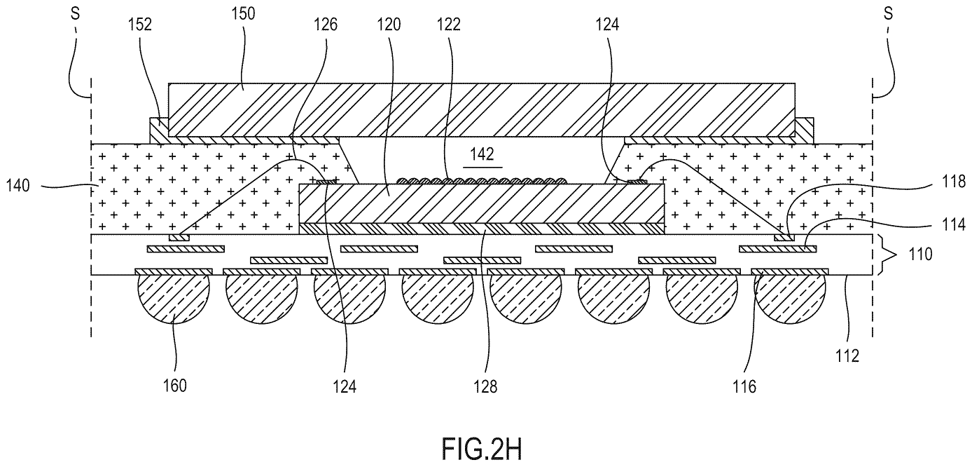

Electronic device 100 can be referred to as a package. In some examples, the overall size of electronic device 100 can be reduced compared to other types of packages. In some examples, a reduced size of cavity 142 can be provided compared to the cavity size of other types of package cavities. In some examples, the size of cavity 142 can be reduced by providing encapsulant 140 cover the top side of electronic component 120 such that the inner sidewall 120x of encapsulant 140 is within the area of the top side of electronic component 120, or within the footprint of electronic component 120. This results in the area of cavity 142 being within the area of the top side of electronic component 120, that is within the footprint of electronic component 120. In addition, the process of providing encapsulant 140 on substrate 110 can eliminate a pre-cut operation as discussed with respect to FIG. 2A though 2H, below.

FIGS. 2A to 2H show cross-sectional views of an example method for manufacturing an example electronic device, such as electronic device 100 in FIG. 1. FIG. 2A shows a cross-sectional view of electronic device 100 at an early stage of manufacture. In the example shown in FIG. 2A, substrate 110 comprising dielectric structure 112 and conductive structure 114 can be provided. Conductive structure 114 can comprise inward terminal 118 at first side 110a of substrate 110 and outward terminal 116 at second side 110b of substrate. In some examples, first side 110a can be referred to as the top side of substrate 110, and second side 110b can be referred to as the bottom side of substrate 110.

Substrate 110 can comprise a core or can be coreless. In some examples, substrate 110 can comprise or be referred to as a rigid printed circuit board, a flexible printed circuit board, a rigid laminate substrate, a flexible laminated substrate, a redistribution layer (RDL) substrate, a build-up substate, a ceramic substrate, a glass substrate, or a silicon substrate. In some examples, an area, or footprint, of substate 110 can varying according to the area or number of electronic components 120 mounted to substrate 110. In some examples, the thickness of substrate 110 can be between about 0.005 mm to about 4 mm.

In some examples, substrate 110 can be an RDL, or build-up, substrate. RDL substrates can comprise one or more conductive redistribution layers and one or more dielectric layers and (a) can be formed layer by layer over an electronic device to which the RDL substrate is coupled, or (b) can be formed layer by layer over a carrier which can be removed, entirely or at least partially, after formation of the RDL substrate. For example, the RDL substate can be formed layer by layer over a carrier, an electronic device can then be connected to the RDL substrate, and the carrier can be removed with the electronic device connected to the RDL substrate. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, or (b) fan-in electrical traces within the footprint of the electronic device. The conductive patterns can be formed using a plating process, for example an electroplating process or an electroless plating process. The conductive patterns can comprise a conductive material, for example copper or other plateable metal. The locations of the conductive patterns can be made using a photo-patterning process, for example a photolithography process and a photoresist material to form a photolithographic mask. The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials, for example, PI, BCB, or PBO. Such dielectric materials can be spun-on or otherwise coated in liquid form rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples, the dielectric materials of the RDL substrates can comprise one or more inorganic dielectric layers. Some examples of one or more inorganic dielectric layers can comprise silicon nitride (Si3N4), silicon oxide (SiO2), or silicon oxynitride (SiON). The one or more inorganic dielectric layers can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, the RDL substrates can omit a permanent core structure such as, for example, a dielectric material comprising BT or FR4 and these types of RDL substrates can comprise or be referred to as a coreless substrate. Substrate 110, as disclosed herein, can comprise an RDL substrate and can be formed on a carrier.

In some examples, substrate 110 can be a pre-formed, or laminate, substrate. The pre-formed/laminate substrates can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or ABF. The pre-formed substrate can include a permanent core structure comprising dielectric material such as, for example, BT or FR4, and dielectric and conductive layers can be provided over the permanent core structure. In other examples, the preformed substrate can be a coreless substrate that omits the permanent core structure. The preformed substrate can be referred to as a printed circuit board (PCB) or a laminate substrate. Such pre-formed substrate can be formed through a semi-additive or modified-semi-additive process.

FIG. 2B shows a cross-sectional view of electronic device 100 at a later stage of manufacture. In the example shown in FIG. 2B, electronic component 120 can be coupled with first side 110a of substrate 110, for example using adhesive 128. The first side, or top side, of electronic component 120 can include image component 122 facing away from substrate 110. The first side of electronic component 120 can also include contact 124 facing away from substrate 110. In some examples, image component 122 can include an image sensor including but not limited to a complementary metal-oxide semiconductor (CMOS) image sensor (CIS). In some examples image component 122 can comprise a lens or an array of lenses, such as a microlens or a microlens array (MLA) although the scope of the disclosed subject matter is not limited in this respect.

FIG. 2C shows a cross-sectional view of electronic device 100 at a later stage of manufacture. In the example shown in FIG. 2C, interconnect 126 is coupled with contact 124 of electronic component 120 and inward terminal 118 of conductive structure 114 of substrate 110. In some examples, interconnect 126 can comprise a wire, although the scope of the disclosed subject matter is not limited in this respect.

FIGS. 2D through 2F show a cross-sectional view of electronic device 100 at a later stage of manufacture. In the example shown in FIG. 2D, mold chase 160 is provided over first side 110a of substrate 120 wherein a mold cavity 164 is provided over first side 110a of substrate 110 according to the shape of mold chase 160. Film 162 can be provided to conform to the shape of mold chase 160 on the mold cavity 164 side of mold chase 160, for example by using a vacuum to cause film 162 to conform to the shape of mold chase 160. Mold cavity 164 defines the regions in which encapsulant 140 can be provided during a molding process. In some examples, film 162 can protect image component 122 from coming into contact with encapsulant 140 during the mold process. In some examples, the shape of mold chase 160 can allow the top side and the lateral side of electronic component 120, contact 124, inward terminal 118, and interconnect 126 to be exposed in mold cavity 164 during the molding process such that these elements can be covered by encapsulant 140.

As shown in FIG. 2E, encapsulant 140 can be provided in mold cavity 164. In some examples, the molding process can comprise a film assisted molding (FAM) process in which a liquid mold is inserted or injected into mold cavity 164 and then cured. As shown in FIG. 2F, after curing, mold chase 160 can be separated and removed and from encapsulant 140 wherein film 162 facilitates the separation to expose the top side and the lateral sides of encapsulant 140. In some examples, the molding process can be the same or a similar molding process as used for manufacturing micro-electromechanical systems (MEMS) or biomedical MEMS (BioMEMS) devices having a cavity, although the scope of the disclosed subject matter is not limited in this respect. After encapsulant 140 is provided, cavity 142 can be defined over the top side of electronic component 120 by the inner sidewall 120x of encapsulant 140, wherein image component 122 is in cavity 142. In some examples, cavity 142 is defined to be within the footprint electronic component 120, such that the area of cavity 142 is contained within the area of the top side of electronic component 120. Encapsulant 140 can cover the top side and lateral sides of electronic component 120, and first side 110 of substrate 110.

FIG. 2G shows a cross-sectional view of electronic device 100 at a later stage of manufacture. In the example shown in FIG. 2G, lid 150 can be provided over cavity 142 over the top side of electronic component 120 and over image component 122. Lid 150 can be over encapsulant 140 and can be coupled to first side 140a of encapsulant with adhesive 152. In some examples, first side 140a of encapsulant 140 can be referred to as the top side of encapsulant 140. In some examples, the area covered by lid 150 can be less than the area of first side 140a of encapsulant 140 such that the lateral side of lid 150 does not extend to the lateral side of encapsulant 140, thereby leaving first side 140a of encapsulant 140 uncovered or exposed. In some examples, adhesive 152 can hermetically seal lid 150 to encapsulant 140 to hermetically isolate cavity 142 from the ambient environment of electronic device 100. In some examples, adhesive 152 can be gas permeable and impervious to liquids or moisture, although the scope of the disclosure subject matter is not limited in this respect. In some examples, lid 150 can comprise a transparent or translucent material such as glass, quartz, or a plastic such as polymethyl methacrylate. In some examples, lid 50 can be transparent to electronic magnetic waves at the wavelength of operation of image component 122, for example infrared light, ultraviolet light, or visible light.

FIG. 2H shows a cross-sectional view of electronic device 100 at a later stage of manufacture. In the example shown in FIG. 2G, external interconnects 160 can be coupled with the second side 110b or bottom side of substrate 110 and can be coupled with outward terminals 116 of conductive structure 114. After providing external interconnects 160, the lateral sides of encapsulant 140 and substrate 110 can be cut or sawed at cut lines S, using a saw or a laser, to provide electronic device 100 at a desired package size. In the manufacturing process shown in FIGS. 2A through 2H, electronic component 120 can be attached to substrate 110 and interconnects 126 can be provided, for example by wire bonding, prior to encapsulant 140 being provided. This disclosed process allows the top side of electronic component 120 to be covered by encapsulant 140 such that a smaller sized cavity 142 can be provided over electronic component 120 and contained within the footprint of electronic component. A reduced size of cavity 142 can reduce a number of foreign material defects in cavity 142 as an artifact the disclosed process. This disclosed process also allows interconnect 126 and inward terminal 118 to be contained within encapsulant 140 instead of being external to encapsulant 140. Furthermore, a pre-cut operation to pre-cut encapsulant 140 at first side 140a and lateral ends of encapsulant 140, occurring prior to providing electronic component 120, prior to providing interconnect 126, and prior to attaching lid, 150 can be eliminated. The distance between a lateral edge of image component 120 and an inner lateral edge of contact 124 can be 650 micrometers (μm) or greater. The distance between the lateral side of electronic component 120 and an inner lateral side of an outermost external interconnect 160 can be 330 μm or greater. The width of adhesive 152 in contact with the bottom side of lid 150 from the interior point of contact to the lateral side of lid 150 can be 580 μm or greater. The distance from the lateral side of lid 150 to the lateral side of encapsulant 140 can be 400 μm or greater. The thickness of encapsulant 140 as measured from the top side of electronic component 120 to first side 140a of encapsulant 140 can be 250 μm or greater. It should be noted that these are merely example ranges for various features of electronic device 100, and the scope of the disclosed subject matter is not limited in these respects.

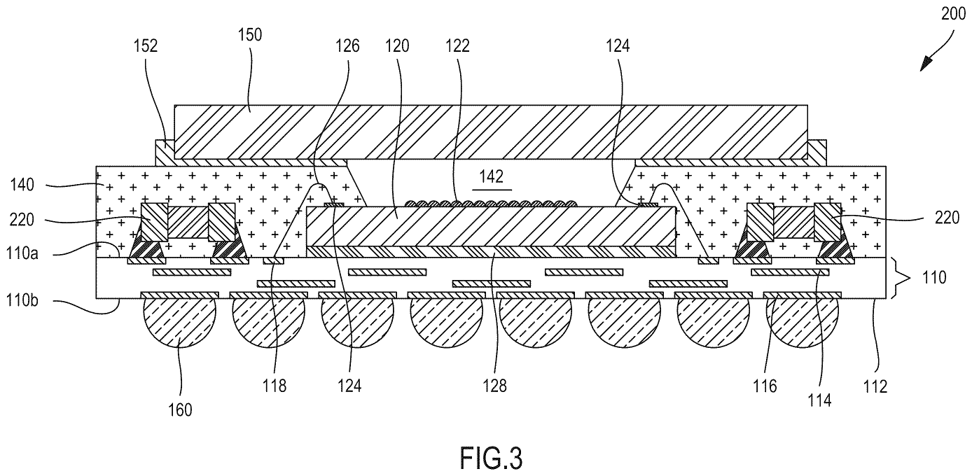

FIG. 3 shows a cross-sectional view of an example of electronic device 200. In the example shown in FIG. 3, electronic device 200 can comprise substrate 110, electronic component 120, image component 122, interconnect 126, encapsulant 140, cavity 142, lid 150, and external interconnects 160, similar to electronic device 100 in FIG. 1. Electronic device 200 can be manufactured using the same or a similar process shown in FIGS. 2A through 2H.

In accordance with various examples, electronic device 200 can further include electronic components 220 coupled with first side 110a of substrate 110 and coupled with conductive structure 114. In some examples, electronic devices can be on either side of electronic component 120 and be located outside of the footprint of cavity 142. Electronic component 220 can comprise an active device or a passive device such as a resistor, capacitor, inductor, transformer, antenna, and so on, and the scope of the disclosed subject matter is not limited in these respects.

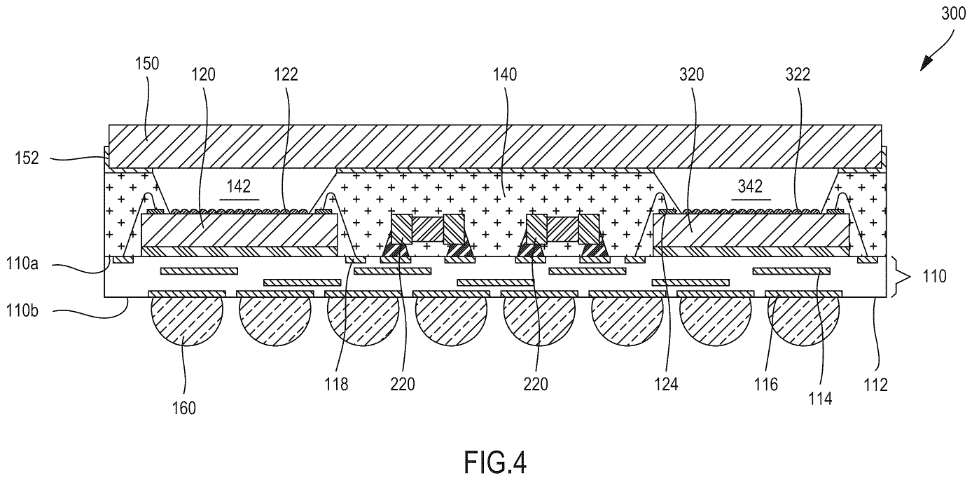

FIG. 4 shows a cross-sectional view of an example of electronic device 300. In the example shown in FIG. 3, electronic device 300 can comprise substrate 110, electronic component 120, image component 122, interconnect 126, encapsulant 140, cavity 142, lid 150, and external interconnects 160, similar to electronic device 100 in FIG. 1 or electronic device 200 of FIG. 2. Electronic device 200 can be manufactured using the same or a similar process shown in FIGS. 2A through 2H.

In accordance with various examples, electronic device 300 can have multiple electronic components and multiple corresponding cavities. For example, encapsulant 140 can define cavity 142 over electronic component 120 and can define cavity 342 over electronic component 320. Image component 122 of electronic component 120 can be in cavity 142, and image component 322 of electronic component 320 can be in cavity 342. In some examples, electronic component 220 can be in encapsulant 140 outside of the footprint of cavity 142 and outside of the footprint of cavity 342. For example, electronic component 220 can be between electronic component 120 and electronic component 320 as shown in FIG. 4. In some examples, electronic device 300 of FIG. 4 can be modified as shown in FIG. 3 to include an electronic component 220 between electronic component 120 at a lateral side of encapsulant 140, or between electronic component 320 and a lateral side of encapsulant 140, with or without an electronic component 220 between electronic component 120 and electronic component 320.

Although FIG. 4 shows a single lid 150 covering both cavity 142 and cavity 342, in some examples two or more lids 150 can be provided with each of the cavities 142 and 342 being covered by a respective one of the lids 150. In such an arrangement, a first lid 150 can be over cavity 142, and a second lid 150 can be over cavity 342, although the scope of the disclosed subject matter is not limited in this respect.

The present disclosure includes reference to certain examples. It will be understood by those skilled in the art, however, that various changes may be made and equivalents may be substituted without departing from the scope of the disclosure. In addition, modifications may be made to the disclosed examples without departing from the scope of the present disclosure. Therefore, it is intended that the present disclosure is not limited to the examples disclosed, but that the disclosure will include all examples falling within the scope of the appended claims.

1. An electronic device, comprising:
a substrate comprising a first side, a second side opposite to the first side, a dielectric structure, and a conductive structure;
a first electronic component over the first side of the substrate, wherein the first electronic component comprises an image component at a first side of the first electronic component facing away from the substrate;
an encapsulant over the first side of the substrate and over the first side of the first electronic component, wherein the encapsulant defines a cavity over the first side of the first electronic component, and wherein the image component is exposed in the cavity;
an interconnect in the encapsulant and coupled with the first electronic component and the conductive structure; and
a lid over the cavity and covering the image component.

2. The electronic device of claim 1, wherein the cavity is contained within an area of the first side of the first electronic component.

3. The electronic device of claim 1, wherein the first electronic component comprises a contact at the first side of the first electronic component, and wherein the interconnect is coupled with the contact and the encapsulant covers the contact.

4. The electronic device of claim 1, wherein the conductive structure comprises an inward terminal at the first side of the substrate, and wherein the interconnect is coupled with the inward terminal and the encapsulant covers the inward terminal.

5. The electronic device of claim 1, wherein the lid is coupled with a first side of the encapsulant with an adhesive.

6. The electronic device of claim 1, wherein a first portion of a first side of the encapsulant is covered by the lid, and a second portion of the first side of the encapsulant is uncovered by the lid.

7. The electronic device of claim 1, wherein a lateral side of the encapsulant is coplanar with a lateral side of the substrate.

8. The electronic device of claim 1, wherein a second side of the first electronic component is coupled with the first side of the substrate with an adhesive.

9. The electronic device of claim 1, wherein the encapsulant covers a lateral side of the first electronic component.

10. The electronic device of claim 1, comprising a second electronic component in the encapsulant and coupled with the first side of the substrate, wherein the second electronic component is outside of a footprint of the cavity.

11. The electronic device of claim 1, wherein the image component comprises an image sensor, and the lid is transparent to light having a wavelength at a wavelength of operation of the image sensor.

12. An electronic device, comprising:
a substrate comprising a top side, a bottom side, a dielectric structure, and a conductive structure;
a first electronic component over the top side of the substrate, wherein the first electronic component comprises a first image component at a top of the first electronic component facing away from the substrate;
a second electronic component over the top side of the substrate, wherein the second electronic component comprises a second image component at a top side of the first electronic component facing away from the substrate;
an encapsulant over the top side of the substrate and over the top side of the first electronic component and the top side of the second electronic component, wherein:
the encapsulant defines a first cavity over the top side of the first electronic component and a second cavity over the top side of the second electronic component;
the first image component is in the first cavity and uncovered by the encapsulant; and
the second image component is in the second cavity and uncovered by the encapsulant;
a first interconnect in the encapsulant and coupled with the first electronic component and the conductive structure;
a second interconnect in the encapsulant and coupled with the second electronic component and the conductive structure; and
a first lid over the encapsulant and covering at least one of the first cavity or the second cavity.

13. The electronic device of claim 12, wherein the first lid covers both the first cavity and the second cavity.

14. The electronic device of claim 12, wherein the first lid covers the first cavity and a second lid covers the second cavity.

15. The electronic device of claim 12, comprising a third electronic component over the top side of the substrate and covered by the encapsulant.

16. The electronic device of claim 15, wherein the third electronic component is between the first electronic component and the second electronic component.

17. A method to manufacture and electronic device, comprising:
providing a substrate comprising a first side, a second side opposite to the first side, a dielectric structure, and a conductive structure;
providing an electronic component over the first side of the substrate, wherein the electronic component comprises an image component at a first side of the electronic component facing away from the substrate;
providing an interconnect coupled to the first side of the electronic component and the first side of the substrate;
providing an encapsulant over the first side of the substrate and over the first side of the electronic component, wherein:
the encapsulant defines a cavity over the first side of the electronic component;
the image component is exposed in the cavity;
the interconnect is in the encapsulant; and
providing a lid over the cavity and covering the image component.

18. The method claim 17, wherein the cavity is contained within an area of the first side of the electronic component.

19. The method of claim 17, wherein the electronic component and the interconnect are provided prior to providing the encapsulant.

20. The method of claim 17, wherein the encapsulant is provided using a film assisted molding (FAM) process.
